(19) United States
(12) Patent Application Publication
(10) Pub. No.: US 2026/0142354 A1
(43) Pub. Date: May 21, 2026

(54) SENSING ASSEMBLY WITH CONTROL MODULES FOR A BATTERY PACK INTERCONNECT ASSEMBLY FOR A BATTERY PACK

(71) Applicant: TE Connectivity Solutions GmbH, Schaffhausen (CH)

(72) Inventor: Evan J. DAWLEY, Troy, MI (US)

(21) Appl. No.: 19/373,918

(22) Filed: Oct. 30, 2025

Related U.S. Application Data
(60) Provisional application No. 63/723,233, filed on Nov. 21, 2024.

(51) Int. Cl. H01M 50/569; G01R 31/36; G01R 31/3835; G01R 31/396; H01M 50/507; H01M 50/519

(52) U.S. Cl. CPC H01M 50/569; G01R 31/3644; G01R 31/3835; G01R 31/396; H01M 50/507; H01M 50/519; H01M 2220/20

(57) ABSTRACT

A battery pack interconnect assembly for electrically connecting cell terminals of battery cells in a battery pack includes a busbar interconnect having busbars arranged rows and columns. The battery pack interconnect assembly includes a sensing assembly coupled to the busbars for sensing at least one parameter of the busbars. The sensing assembly includes a control assembly and a sensing harness coupled to the control assembly having sensing cables with sensing conductors coupled to the busbars at sensing points. The control assembly includes a control circuit board and control modules coupled to control circuits of the control circuit board. Each control module includes module terminals coupled between the control circuits and the corresponding sensing conductors.

### CROSS REFERENCE TO RELATED APPLICATIONS

This application claims the benefit of U.S. Provisional Application No. 63/723,233, filed 21 Nov. 2024, the subject matter of which is herein incorporated by reference in its entirety.

### BACKGROUND OF THE INVENTION

The subject matter herein relates generally to battery packs, such as battery packs for electric vehicles.

Electric vehicles include a battery system including a battery pack having a large number of battery cells. A typical battery system requires a connectivity solution to transfer/distribute power between groups of battery cells and have provisions for sensing battery parameters like voltage and temperature. To transfer power, busbars (aluminum or copper) are usually welded to the cell terminals in serial and/or parallel electrical configuration. As electric vehicle applications proliferate, the overhead cost of components ($/kWh) is scrutinized and there is a desire to minimize costs, such as by minimizing the part count and part numbers. For battery systems of electric vehicles, the battery cell stack sizes are very large. Typically, assembly of the battery system requires many parts, which are individually assembled to the corresponding cell terminals, which is time consuming and adds cost to the assembly process. There is a need to monitor operating parameters of the components, such as voltages at each of the busbars, temperature, charge state, or other operating characteristics. Some systems use wire harnesses with sensors to monitor the components of the battery system. The wire harnesses add weight, cost, and assembly time.

A need remains for a method for assembling battery packs, such as for electric vehicles, in a cost effective and reliable manner.

### BRIEF DESCRIPTION OF THE INVENTION

In an embodiment, a battery pack interconnect assembly for electrically connecting cell terminals of battery cells in a battery pack is provided. The battery pack interconnect assembly includes a busbar interconnect that includes a plurality of busbars arranged in a matrix having multiple rows of the busbars and multiple columns of the busbars and a busbar carrier holding the busbars. Each busbar includes a first mating end for mating with the corresponding cell terminal of the corresponding battery cell and a second mating end for mating with the adjacent cell terminal of the adjacent corresponding battery cell. The busbars electrically connect the battery cells in the battery pack. The battery pack interconnect assembly includes a sensing assembly coupled to the busbars for sensing at least one parameter of the busbars. The sensing assembly includes a control assembly and a sensing harness coupled to the control assembly. The sensing harness has sensing cables with sensing conductors coupled to the busbars at sensing points. The control assembly includes a control circuit board and control modules coupled to control circuits of the control circuit board. Each control module includes module terminals coupled between the control circuits and the corresponding sensing conductors.

In another embodiment, a sensing assembly for sensing parameters of busbars electrically connecting to cell terminals of battery cells in a battery pack is provided. The sensing assembly includes a sensing harness that includes sensing modules and sensing cables coupled to the sensing modules. The sensing modules are configured to be electrically connected to the corresponding busbars at sensing points to sense the sensing parameters of each of the corresponding busbars. Each sensing module includes a sensing housing and a sensing circuit held by the sensing housing. The sensing circuits configured to be electrically connected to the corresponding busbars. The sensing cables extend parallel to each other in rows. The sensing cables are flat flexible cables having a plurality of sensing conductors. The sensing cables span each of the sensing modules. The sensing conductors are electrically connected to the corresponding sensing circuits of each of the sensing modules. The sensing assembly includes a control assembly coupled to the sensing cables of the sensing harness. The control assembly includes a control circuit board and control modules coupled to the control circuit board. Each control module includes module terminals coupled to control circuits of the control circuit board. The module terminals include mating portions coupled to the sensing conductors of the corresponding sensing cable. The control modules electrically connect the corresponding sensing cable to the control circuit board.

In a further embodiment, a battery pack is provided and includes battery cells arranged in a matrix having multiple rows and multiple columns of the battery cells. Each battery cell includes a first cell terminal and a second cell terminal. The battery pack includes a battery pack interconnect assembly electrically connected to the first and second cell terminals of the battery cells. The battery pack interconnect assembly includes a busbar interconnect and a sensing assembly electrically connected to the busbar interconnect. The busbar interconnect includes a plurality of busbars arranged in a matrix having multiple rows of the busbars and multiple columns of the busbars and a busbar carrier holding the busbars. Each busbar includes a first mating end for mating with the first cell terminal of the corresponding battery cell and a second mating end for mating with the second cell terminal of the adjacent corresponding battery cell. The busbars electrically connect the battery cells in the battery pack. The sensing assembly includes a sensing harness and a control assembly coupled to the sensing harness. The sensing harness includes sensing modules and sensing cables coupled to the sensing modules. The sensing modules electrically connect to the corresponding busbars at sensing points to sense sensing parameters of each of the corresponding busbars. Each sensing module includes a sensing housing and a sensing circuit held by the sensing housing. The sensing circuits configured to be electrically connected to the corresponding busbars. The sensing cables extending parallel to each other in rows. The sensing cables are flat flexible cables having a plurality of sensing conductors. The sensing cables span each of the sensing modules. The sensing conductors are electrically connected to the corresponding sensing circuits of each of the sensing modules. The control assembly coupled to the sensing cables of the sensing harness. The control assembly includes a control circuit board and control modules coupled to the control circuit board. Each control module includes module terminals coupled to control circuits of the control circuit board. The module terminals include mating portions coupled to the sensing conductors of the corresponding sensing cable. The control modules electrically connect the corresponding sensing cable to the control circuit board.

### BRIEF DESCRIPTION OF THE DRAWINGS

FIG. 1 is a perspective view of a battery pack including a battery pack interconnect assembly in accordance with an exemplary embodiment.

FIG. 2 is a top view of the battery pack interconnect assembly in accordance with an exemplary embodiment.

FIG. 3 is a top view of the sensing module in accordance with an exemplary embodiment.

FIG. 4 is a side view of the sensing module in accordance with an exemplary embodiment.

FIG. 5 is a top view of the sensing cable in accordance with an exemplary embodiment.

FIG. 6 is a cross-sectional view of the sensing cable in accordance with an exemplary embodiment.

FIG. 7 illustrates the sensing assembly in accordance with an exemplary embodiment.

FIG. 8 is a perspective view of the control module in accordance with an exemplary embodiment.

FIG. 9 is a bottom perspective view of a portion of the control assembly showing the control module poised for mating with the control circuit board in accordance with an exemplary embodiment.

FIG. 10 is a bottom view of the control assembly in accordance with an exemplary embodiment.

FIG. 11 is a top view of the control assembly in accordance with an exemplary embodiment.

FIG. 12 is a cross-sectional view of the control assembly in accordance with an exemplary embodiment.

FIG. 13 is a cross-sectional view of the control assembly in accordance with an exemplary embodiment.

FIG. 14 is a cross-sectional view of the control assembly in accordance with an exemplary embodiment showing the sensing conductor being terminated to the module terminal by an ultrasonic welding process.

FIG. 15 is a cross-sectional view of the control assembly in accordance with an exemplary embodiment showing the sensing conductor being terminated to the module terminal by a laser welding process.

FIG. 16 is a cross-sectional view of the control assembly in accordance with an exemplary embodiment showing the sensing conductor being terminated to the module terminal by a resistance welding process.

FIG. 17 is a cross-sectional view of the control assembly in accordance with an exemplary embodiment showing the sensing conductor being terminated to the module terminal by a resistance welding process.

### DETAILED DESCRIPTION OF THE INVENTION

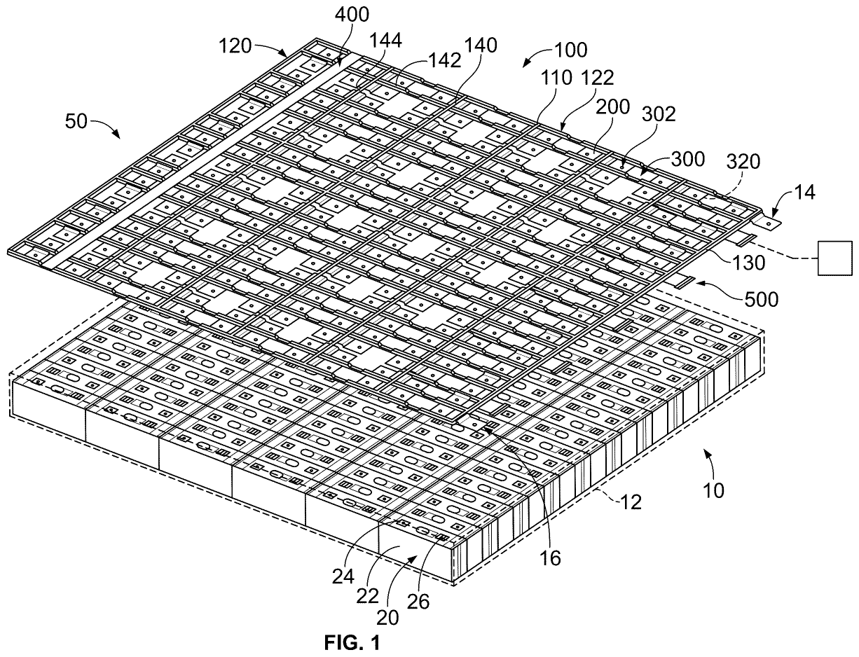

FIG. 1 is a perspective view of a battery pack 10 including a battery pack interconnect assembly 50 in accordance with an exemplary embodiment. The battery pack interconnect assembly 50 includes a busbar interconnect 100 having a plurality of busbars 200. The battery pack interconnect assembly 50 includes a sensing assembly 500 including a sensing harness 300 and a control assembly 400 coupled to the sensing harness 300. The sensing harness 300 senses one or more operating parameters of the battery pack 10, such as voltage, temperature, charge state, or other operating characteristics of the battery pack 10. The control assembly 400 receives the sensor data from the sensing harness 300 and may control one or more operations associated with the battery pack 10, such as charging operation. For example, the control assembly 400 may be communicatively coupled to a battery control module, battery distribution unit, or other control device for the battery system. The control assembly 400 may aggregate the sensor data, such as for each of the busbars 200.

The battery pack 10 may be a battery pack for a vehicle, such as an electric vehicle. However, the battery pack 10 may be used in other applications in alternative embodiments. In an exemplary embodiment, the battery pack 10 is a high voltage battery pack. For example, the battery pack 10 may be a 400V or 800V battery pack. The busbar interconnect 100 is used to electrically connect a matrix of battery cells 20 of the battery pack 10. For example, the busbar interconnect 100 may electrically connect the battery cells 20 in series and/or parallel.

The battery cells 20 may be held in a battery pack housing 12. The battery pack 10 includes a positive battery interconnect terminal 14 and a negative battery interconnect terminal 16. The battery interconnect terminals 14, 16 may interface to other power distribution components of the battery pack 10, such as contactors and fuses for connection to a charging system and/or a load, such as an electric motor.

Each battery cell 20 includes a cell housing 22, a first cell terminal 24, and a second cell terminal 26. The battery cell 20 may be a prismatic battery cell in various embodiments. The first and second cell terminals 24, 26 may be cathode and anode terminals. In an exemplary embodiment, the battery cell 20 are rectangular and arranged in a stacked configuration. For example, the battery cells 20 may be stacked in rows and columns of battery cells 20 in the matrix. The cell matrix may have a large surface area, such as greater than two square meters (2 m² or more). For example, the matrix may have a length of between approximately 1.0 m and 2.0 m and a width of between approximately 1.0 m and 1.5 m. Adjacent battery cells 20 in the rows are interconnected by the corresponding busbars 200 of the busbar interconnect 100. Adjacent rows of the battery cells 20 are interconnected by the corresponding busbars 200 of the busbar interconnect 100. For example, end battery cells 20 may be connected row-to-row.

The busbar interconnect 100 includes a busbar carrier 110 holding the busbars 200. The busbar carrier 110 holds the busbars 200 at relative locations for mating with the cell terminals 24, 26 of the corresponding battery cells 20. The busbars 200 electrically connect adjacent battery cells 20, such as in series and/or in parallel. In various embodiments, the busbar carrier 110 integrates all of the busbars 200 into a single unit or structure for mounting to the matrix of battery cells 20. For example, a single busbar carrier 110 may be used to hold all of the busbars 200. In other various embodiments, the busbar carrier 110 may include multiple frames or units, each holding a plurality of the busbars 200, such as a column of the busbars 200. The frames/units may be connected together by other elements of the busbar carrier 110 to form a connected structure.

In various embodiments, the busbar carrier 110 may be a structural foam leadframe that holds the busbars 200. For example, the busbar carrier 110 may be manufactured by a structural foam molding process. The busbar carrier may be manufactured from other materials in alternative embodiments, such as a molded plastic structure. The busbar carrier 110 may be molded or formed on the busbar matrix. For example, the busbar carrier 110 may be overmolded in situ over portions of the busbars 200 to form the busbar interconnect 100. The busbar carrier 110 may be formed around portions of the busbars 200 to hold the busbars 200 relative to each other and relative to the cell terminals 24, 26 of the battery cells 20.

In an exemplary embodiment, the busbar carrier 110 includes a framework or lattice 120. The lattice 120 is formed around portions of the busbars 200 to hold the busbars 200 at relative positions. In an exemplary embodiment, the busbar carrier 110 holds all of the busbars 200 for the battery pack 10 to reduce part count for final assembly to the battery pack 10. For example, the single busbar interconnect 100 is assembled to the battery pack 10. The busbar carrier 110 is used to position the busbars 200 for electrical connection to the cell terminals 24, 26 of the battery cells 20. In an exemplary embodiment, the sensing assembly 500, such as the sensing harness 300 and/or the control assembly 400, is coupled to the busbar carrier 110. The busbar carrier 110 may be used to position the sensing assembly 500 on the battery cells 20.

The lattice 120 includes frame members 122 configured to be coupled to the busbars 200 to hold relative positions of the busbars 200. The frame members 122 include outer frame members 130 surrounding a perimeter of the lattice 120 and inner frame members 140 spanning across an interior of the lattice 120 to interface with the busbars 200. The inner frame members 140 extend between the outer frame members 130. For example, the inner frame members 140 include longitudinal elements 142 and lateral elements 144. The longitudinal elements 142 extend longitudinally across the lattice 120 between the opposite ends. The lateral elements 144 extend laterally across the lattice 120 between the opposite sides. The longitudinal elements 142 and/or the lateral elements 144 may be used to support portions of the busbars 200. The lateral elements 144 interconnect the longitudinal elements 142, such as to provide support to the longitudinal elements 142, and vice versa. In an exemplary embodiment, the inner frame members 140 are formed integral with the outer frame members 130. For example, the inner frame members 140 are formed along with the outer frame members 130 during a structural molding process. The lattice 120 forms a unitary, monolithic structure.

In an exemplary embodiment, the lateral elements 144 span across the columns of busbars 200. The lateral elements 144 engage the busbars 200 to support the busbars 200. The lateral elements 144 support each of the busbars 200 in the corresponding columns. In an exemplary embodiment, the longitudinal elements 142 are located in the gaps between the rows of the busbars 200. The longitudinal elements 142 may be used to support at least some of the busbars 200. However, in alternative embodiments, the longitudinal elements 142 may additionally or alternatively be used to support some or all of the busbars 200.

In an exemplary embodiment, the sensing harness 300 has sensing points 302 for monitoring the busbars 200 and/or the cell terminals 24, 26. For example, the sensing harness 300 is electrically connected to the busbars 200 at the sensing points 302 to monitor voltage, temperature, charge state, or other operating characteristics of the busbars 200 and/or the cell terminals 24, 26. The sensing harness 300 is configured to be electrically connected to the control assembly 400. The sensing harness 300 sends sensing signals from the sensing points 302 to the control assembly 400, which may be used to control operation of the vehicle and/or a charging operation of the vehicle.

The battery pack interconnect assembly 50 provides a large format battery cell interconnect assembly that is configured to be mounted to the battery pack 10 (for example, each of the battery cells 20), such as a single unit. The busbar carrier 110 holds the busbars 200 at proper locations for termination to the cell terminals 24, 26 of each of the battery cells 20 of the battery pack 10. By holding the busbars 200 for assembly to the battery cells 20 of the battery pack 10, assembly processes may be eliminated, such as with conventional battery systems where each of the busbars are assembled to the battery cells individually with multiple assembly steps. The busbar interconnect 100 reduces the overall part number count and reduces the number of handled components during assembly of the battery pack 10. The busbar carrier 110 may have a large format and surface area. For example, the structural process to manufacture the lattice framework for the busbar carrier 110 enables a large footprint for the busbar carrier 110. The structural material of the lattice framework for the busbar carrier 110 is dimensionally stable and does not tend to warp making assembly and termination to the battery cells more simple, quicker, and lower cost compared to conventional assembly processes.

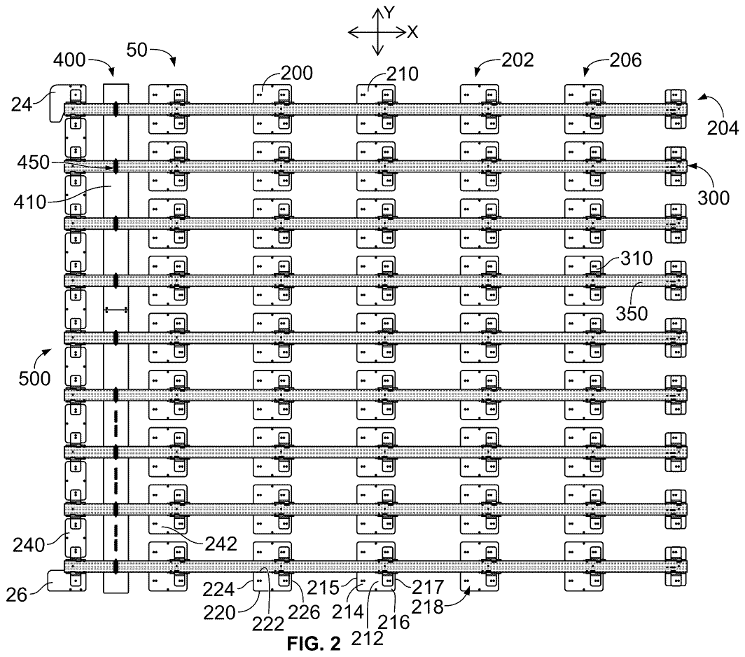

FIG. 2 is a top view of a portion of the battery pack interconnect assembly 50 in accordance with an exemplary embodiment. FIG. 2 illustrates a matrix 202 of the busbars 200 and the sensing assembly 500 coupled to the busbars 200. The busbars 200 are arranged in rows 204 and columns 206 in the matrix 202. The arrangement of the busbars 200 corresponds to the arrangement of the battery cells 20 to connect to the corresponding cell terminals 24, 26. The sensing harness 300 traverses the rows 204 and columns 206 of the busbars 200 to electrically connect to each of the busbars 200 for sensing characteristics (for example, voltages) of each of the busbars 200. The control assembly 400 may be integrated into the matrix of busbars 200, such as between some of the columns 206 or some of the rows 204, or may be located outside of the matrix 202, such as along a side of the matrix 202 of the busbars 200.

Each busbar 200 includes a metal plate 210 having a main body 212, a first mating pad 214 at a first mating end 215, and a second mating pad 216 at a second mating end 217. The first mating pad 214 is configured to connect to a cell terminal 24 of one of the battery cells 20. The second mating pad 216 is configured to connect to a cell terminal 26 of an adjacent battery cell 20. The busbar 200 electrically connects the adjacent battery cells 20. The mating pads 214, 216 may include openings 218 therethrough, such as for locating the busbars 200 relative to the cell terminals 24, 26. The openings 218 may be used for a pick and place operation. The openings 218 may be used to hold positions of the busbars 200 during the overmolding process of forming the busbar carrier 110.

In an exemplary embodiment, each busbar 200 is generally rectangular. For example, the busbar 200 includes a first end 220, a second end 222, a first side 224, and a second side 226. The busbar 200 may be elongated, such as having the ends 220, 222 longer than the sides 224, 226. In an exemplary embodiment, the busbar is generally planar. For example, the first and second mating pads 214, 216 may be coplanar for attachment to the cell terminals 24, 26. Optionally, the main body 212 may be offset or out of plane relative to the first and second mating pads 214, 216, such as located above or below the plane of the first and second mating pads 214, 216. The busbar 200 may include mounting features, such as mounting tabs, posts, brackets, clips, notches, openings, and the like for mounting the busbar 200 to the busbar carrier 110.

In an exemplary embodiment, the matrix 202 of the busbars 200 include eighteen rows 204 of the busbars 200 and seven columns 206 of the busbars 200. Greater or fewer busbars 200 may be provided in the rows 204 and/or the columns 206 in alternative embodiments. In an exemplary embodiment, the busbars 200 include outer busbars 240 and inner busbars 242. The outer busbars 240 are arranged along the opposite sides of the busbar matrix 202 (for example, right side and left side). The outer busbars 240 are used to connect between two different rows of the battery cells 20. The inner busbars 242 extend between the outer busbars 240. The inner busbars 242 are used to connect the adjacent battery cells 20 within the same column. The outer busbars 240 are oriented perpendicular to the inner busbars 242. For example, the inner busbars 242 are oriented longitudinally and the outer busbars 240 are oriented laterally. Other orientations are possible in alternative embodiments.

The sensing harness 300 includes sensing modules 310 and sensing cables 350 coupled to each of the sensing modules 310. The sensing modules 310 are used to electrically connect the sensing cables 350 with the corresponding busbars 200. However, in alternative embodiments, the sensing harness 300 may be provided without the sensing modules 310. Rather, the sensing cables 350 may be directly coupled to the busbars 200. The sensing modules 310 and the sensing cables 350 form a covering structure that overlaps the matrix 202 of the busbars 200. The sensing modules 310 may extend generally in the Y direction and the sensing cables 350 may extend generally in the X direction. In an exemplary embodiment, the sensing cables 350 are flat flexible cables having a plurality of flat conductors arranged in an insulator configured to be electrically connected to corresponding rows of the sensing modules 310.

In an exemplary embodiment, the sensing modules 310 extend along the columns 206 of the busbars 200 and are electrically connected to the corresponding busbars 200 in the column 206 at the corresponding sensing points 302. The sensing modules 310 sense characteristics, such as voltage, of each of the corresponding busbars 200. The sensing cables 350 span each of the sensing modules 310 and are electrically connected to the sensing modules 310 to aggregate the signals from the sensing modules 310. The sensing cables 350 are electrically connected to the control assembly 400.

The control assembly 400 includes a control circuit board 410 and control modules 450 coupled to the control circuit board 410. In an exemplary embodiment, an electrical connector 440 is coupled to the control circuit board 410 and is configured to be electrically connected to another component of the battery system, such as a battery distribution unit or battery control module of the vehicle.

Each control module 450 is coupled to the corresponding sensing cable 350. The control circuit board 410 aggregates the signals from the control modules 450 and the corresponding sensing cables 350. The control circuit board 410 may be a rigid printed circuit board. In other various embodiments, the control circuit board 410 may be a flexible circuit board. In an exemplary embodiment, the control assembly 400 is a low profile interconnect solution to connect the sensing harness 300 to the electrical connector 440. The sensing cables 350 may be electrically connected to the control modules 450, such as by a welding process (for example, ultrasonic welding, resistance welding, laser welding, and the like).

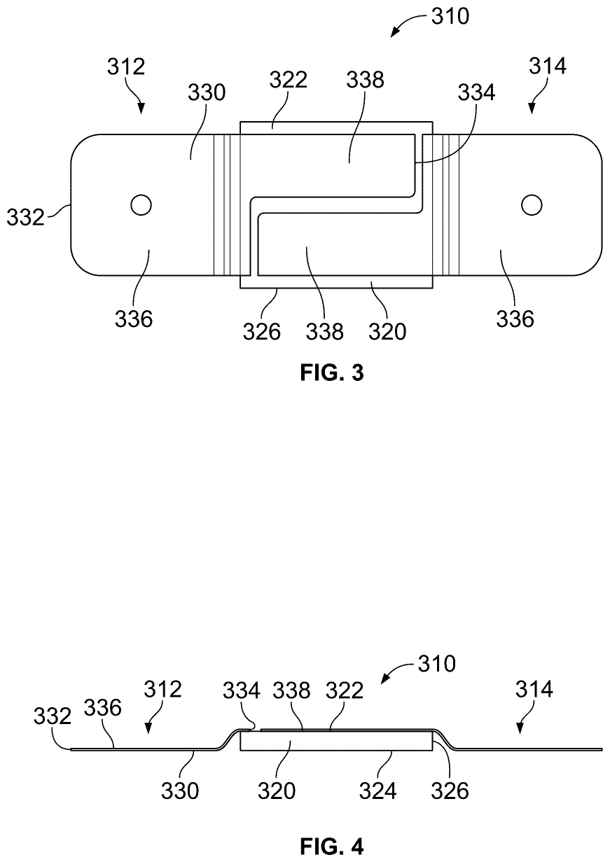

FIG. 3 is a top view of the sensing module 310 in accordance with an exemplary embodiment. FIG. 4 is a side view of the sensing module 310 in accordance with an exemplary embodiment. In an exemplary embodiment, the sensing module 310 includes a sensing housing 320 and one or more sensing circuits. In the illustrated embodiment, the sensing module 310 includes a pair of the sensing circuits, namely a first sensing circuit 312 and a second sensing circuit 314. The sensing module 310 may include greater or fewer sensing circuits 312, 314 in alternative embodiments. In various embodiments, the sensing circuits 312, 314 may be electrically connected to different busbars 200. In other various embodiments, the sensing circuits 312, 314 may be connected to the same busbar 200 to define multiple points of contact with the same busbar 200 and thus define a redundant connection for improved reliability.

In an exemplary embodiment, the sensing housing 320 is manufactured from an electrically insulating material, such as a dielectric material, such as a plastic material. The sensing housing 320 may be a molded part. In various embodiments, the sensing housing 320 is formed in place on the sensing circuits 312, 314. For example, the sensing housing 320 may be overmolded over portions of the sensing circuits 312, 314. The sensing module 310 may be an overmolded leadframe. In alternative embodiments, the sensing housing 320 may be preformed and the sensing circuits 312, 314 may be coupled to the sensing housing 320. In the illustrated embodiments, the sensing housing 320 includes a top 322, a bottom 324, and side edges 326 between the top 322 and the bottom 324. The sensing housing 320 may be generally rectangular. However, the sensing housing 320 may have other shapes in alternative embodiments. The bottom 324 may be mounted to one or more of the busbars 200 and/or the busbar carrier 110. In an exemplary embodiment, the sensing circuits 312, 314 may extend along the top 322, such as for connection to the sensing cable 350.

The first and second sensing circuits 312, 314 may be similar to each other and include similar structures. Like elements may be identified herein using like reference numerals. The sensing circuit 312 includes a sensing contact 330 extending between a first end 332 and a second end 334. In an exemplary embodiment, the sensing contact 330 is a stamped and formed contact being stamped from a metal sheet and bent or formed into a predetermined shape. The sensing contact 330 may include a busbar. In alternative embodiments, the sensing circuit 312 may include a flexible circuit, such as a flat flexible cable, a flexible printed circuit board, a ribbon cable, or other type of flexible circuit.

The sensing contact 330 includes a first mating tab 336 at the first end 332 and a second mating tab 338 at the second end 334. In the illustrated embodiment, the first and second mating tabs 336, 338 are at different vertical heights. For example, the first mating tab 336 may be generally coplanar with the bottom 324 of the second housing 320 and the second mating tab 338 is generally coplanar with the top 322 of the second housing 320. The first mating tab 336 is configured to be electrically connected to the busbar 200. For example, the first mating tab 336 may be coupled to the busbar 200 by a welded connection, a conductive bonding connection, a staking connection, or a conductive adhesive connection. In the illustrated embodiments, the second mating tab 338 extends along the top 322 of the sending housing 320. The second mating tab 338 is configured to be electrically connected to the sensing cable 350. For example, the second mating tab 338 may be coupled to the sensing cable 350 by a welded connection, a conductive bonding connection, a staking connection, or a conductive adhesive connection.

In an exemplary embodiment, the second mating tabs 338 of the first and second sensing circuits 312, 314 may be overlapping at the top 322. For example, the second mating tabs 338 may bypass each other on opposite sides of the sensing housing 320. The second mating tabs 338 may be spaced apart from each other by a gap. The second mating tabs 338 are electrically isolated from each other for electrical connection to different busbars 200.

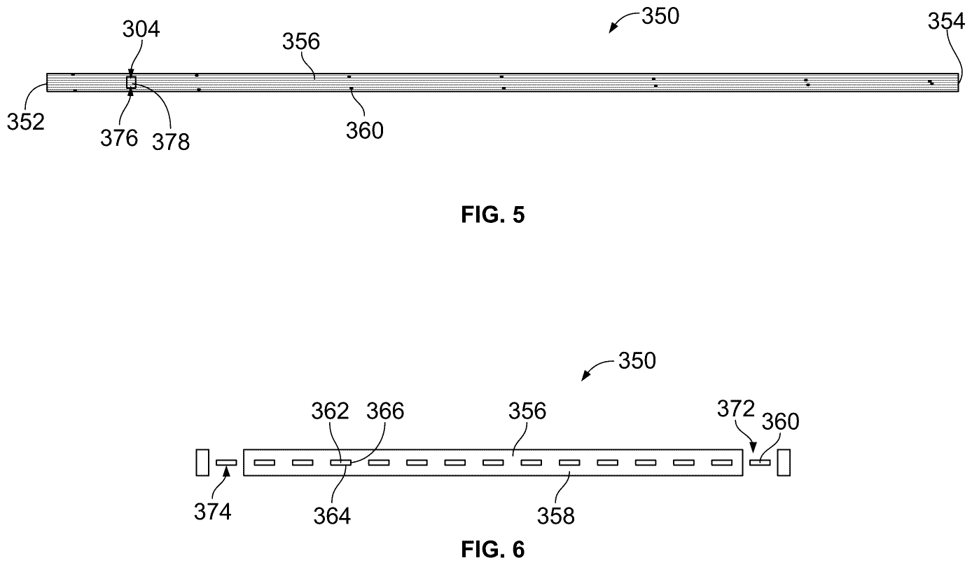

FIG. 5 is a top view of the sensing cable 350 in accordance with an exemplary embodiment. FIG. 6 is a cross-sectional view of the sensing cable 350 in accordance with an exemplary embodiment. In an exemplary embodiment, the sensing cable 350 is a flat flexible cable. The sensing cable 350 extends between a first end 352 and a second end 354. The sensing cable 350 includes a connection region 304 configured to be connected to the control assembly 400. The connection region 304 may be provided at one of the ends, such as the first end 352, or may be provided at a central location, such as remote from the first and second ends 352, 354.

The sensing cable 350 includes an insulator 356 holding a plurality of sensing conductors 360. The insulator 356 may include one or more layers of flexible plastic film 358, such as an upper film, a lower film, and may include one or more intermediate films between the upper and lower films. The layers may be connected by adhesive. The insulator 356 may be a laminated structure. In other various embodiments, the insulator 356 may be extruded around the sensing conductors 360. The sensing conductors 360 are sandwiched between layers of the flexible plastic film 358. The films 358 may be manufactured from a polyester-based material, polyethylene-based material, polyamide-based material, polyurethane-based material, PVC material, and the like. The films 358 may be laminated to each other and/or to the sensing conductors 360, such as using one or more adhesive layers, to form a single, flexible unit.

The sensing conductors 360 are flat, parallel conductors. The sensing conductors 360 may be copper, aluminum, or other metal material. Each sensing conductor 360 includes an upper surface 362 and a lower surface 364. The sensing conductor 360 includes sides 366 between the upper and lower surfaces 362, 364. In an exemplary embodiment, the sensing conductors 360 have a rectangular cross-section. The films 358 cover the upper and lower surfaces 362, 364. The films 358 may be located between the sides 366 of the adjacent sensing conductors 360.

In the illustrated embodiment, the sensing cable 350 includes fifteen of the sensing conductors 360. The sensing cable 350 may include greater or fewer sensing conductors 360 in alternative embodiments, such as to accommodate the number of busbar voltage signals, or other components such as temperature sensors, to be measured, which may be dependent on the number of battery cells. In an exemplary embodiment, the sensing conductors 360 each have the same size (for example, height and width). However, in alternative embodiments, the sensing conductors 360 may have different sizes. In an exemplary embodiment, the sensing cable 350 may have a common pitch or spacing between the sensing conductors 360. However, in alternative embodiments, the sensing cable 350 may have different pitches between the sensing conductors 360.

In an exemplary embodiment, the sensing cable 350 includes connecting access windows 372 exposing the corresponding sensing conductors 360 at joining points 378. For example, portions of the insulator 356 may be selectively removed to form the connecting access windows 372 and expose the corresponding sensing conductors 360. In various embodiments, the insulator 356 may be removed by ablation, skiving, cutting, or other removal processes. The connecting access windows 372 provide access to the sensing conductors 360 at the joining points 378 for electrical connection to the sensing circuits 312, 314 of the sensing modules 310. For example, the sensing conductors 360 may be electrically connected to the corresponding sensing circuits 312, 314 by one of a welded connection, a conductive bonding connection, a staking connection, or a conductive adhesive connection. In an exemplary embodiment, the sensing conductors 360 are connected to the corresponding sensing circuits 314, 314 by ultrasonic welding, resistance welding, laser welding, or other similar welding process. In an exemplary embodiment, the connecting access windows 374 expose different sensing conductors 360 along different segments of the sensing cable 350 for connection to different sensing modules 310. For example, each sensing conductor 360 may be exposed at a different location along the length of the sensing cable 350 for connection to a different sensing module 310.

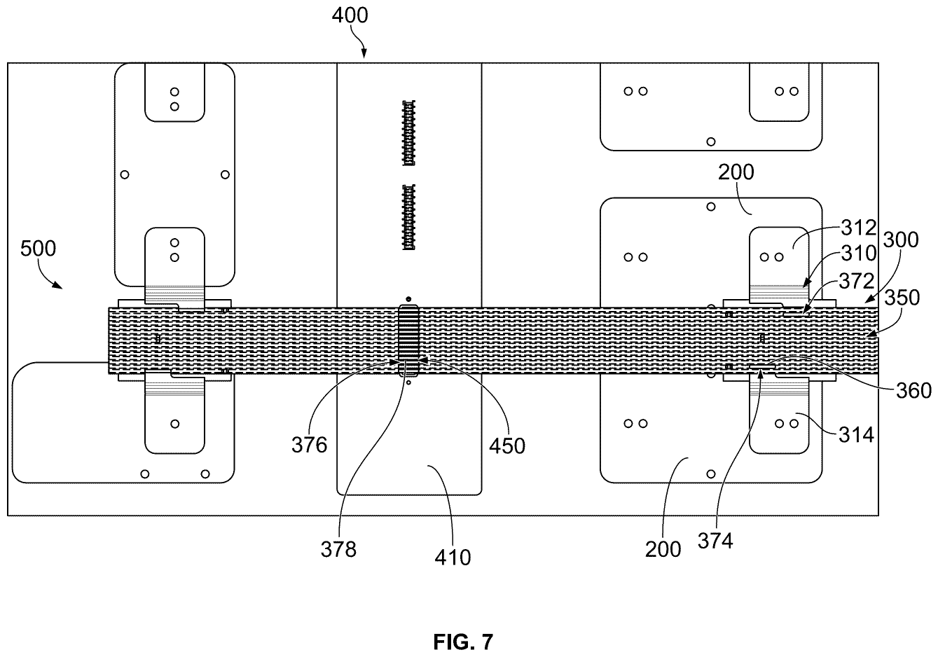

In an exemplary embodiment, the sensing cable 350 (further shown in FIG. 7) includes a module access window 376 exposing the corresponding sensing conductors 360, such as all of the sensing conductors 360, at joining points 378. For example, portions of the insulator 356 may be removed to form the module access window 376 and expose the corresponding sensing conductors 360. In various embodiments, the insulator 356 may be removed by ablation, skiving, cutting, or other removal processes. The module access window 376 provides access to the sensing conductors 360 at the joining points 378 for electrical connection to the control module 450 of the control assembly 400. For example, the sensing conductors 360 may be electrically connected to the control module 450 by one of a welded connection, a conductive bonding connection, a staking connection, or a conductive adhesive connection. In an exemplary embodiment, the sensing conductors 360 are connected to the control module 450 by ultrasonic welding, resistance welding, laser welding, or other similar welding process.

FIG. 7 illustrates the sensing assembly 500 in accordance with an exemplary embodiment. FIG. 7 shows the sensing harness 300 and the control assembly 400. The sensing harness 300 includes the sensing modules 310 and the sensing cables 350 coupled to the sensing modules 310. The sensing cables 350 are coupled to the control circuit board 410 via the control modules 450. The sensing cables 350 extend laterally across the sensing modules 310, such as along the rows of the sensing modules 310, to overlap the sensing modules 310 and electrically connect to each of the sensing modules 310 in the corresponding row. The sensing cables 350 are flat flexible cables having a plurality of flat conductors electrically connected to the corresponding sensing modules 310.

The sensing modules 310 are coupled to the busbars 200. For example, the sensing circuits 312, 314 may be electrically connected to the corresponding busbars 200 by one of a welded connection, a conductive bonding connection, a staking connection, or a conductive adhesive connection. The sensing circuits 312, 314 may be welded to the busbars 200 at the same time the busbars 200 are welded to the battery cells, so there is no pre-welding necessary and assembly may be simplified.

During assembly, the sensing conductors 360 are electrically connected to the sensing circuits 312, 314 at the corresponding joining points 378. For example, the connecting access windows 372 expose the sensing conductors 360 for electrical connection to the sensing circuits 312, 314. The sensing conductors 360 may be electrically connected to the corresponding sensing circuits 312, 314 by one of a welded connection, a conductive bonding connection, a staking connection, or a conductive adhesive connection. The connecting access windows 374 expose different sensing conductors 360 along different segments of the sensing cable 350 for connection to different sensing modules 310.

During assembly, the sensing conductors 360 are electrically connected to the control module 450 at the corresponding joining points 378. For example, the module access window 376 exposes the sensing conductors 360 for electrical connection to the control module 450. The sensing conductors 360 may be electrically connected to module terminals of the control module 450 by one of a welded connection, a conductive bonding connection, a staking connection, or a conductive adhesive connection.

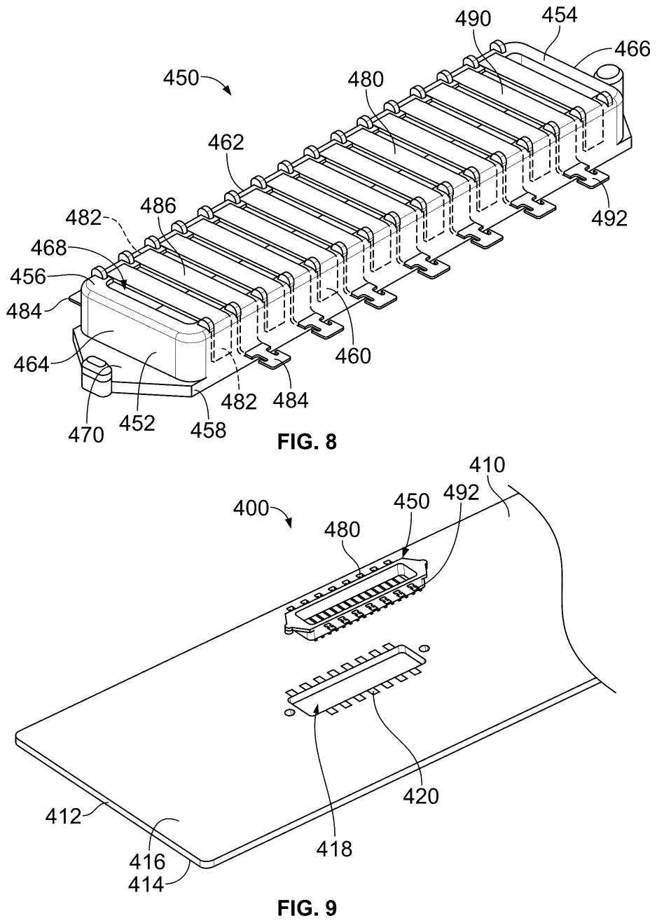

FIG. 8 is a perspective view of the control module 450 in accordance with an exemplary embodiment. In an exemplary embodiment, the control module 450 is an electrical connector configured to be electrically connected to the control circuit board 410. The control module 450 is configured to be electrically connected to the sensing conductors 360 of the sensing cable 350.

The control module 450 includes a module housing 452 having walls 454 that support module terminals 480. The module housing 452 extends between a top 456 and the bottom 458. The module housing 452 includes a first side 460 and a second side 462 opposite the first side 460. The module housing 452 includes a first end 464 and a second end 466 opposite the first end 464. The walls 454 may be provided at the sides 460, 462 and/or the ends 464, 466. In an exemplary embodiment, the module housing 452 includes an opening 468 between the sides 460, 462 and/or the ends 464, 466. The opening 468 may be open at the top 456 and/or the bottom 458. The module terminals 480 are exposed in the opening 468, such as for termination to the sensing conductors 360 of the sensing cable 350. In the illustrated embodiment, the module housing 452 is generally rectangular shaped. The module housing 452 may have other shapes in alternative embodiments in an exemplary embodiment, the module housing 452 includes one or more mounting brackets 470, such as at the ends 464, 466 for mounting the control module 450 to the control circuit board 410. Other types of securing features may be used in alternative embodiments.

The module terminals 480 are electrically conductive. For example, the module terminals 480 may be manufactured from a metal material, such as copper or aluminum. In an exemplary embodiment, the module terminals 480 are stamped and formed terminals. In various embodiments, the module terminals 480 may be a stamped lead frame that is overmolded by an overmolded body forming a module housing 452. For example, the module housing 452 may be formed in place around the module terminals 480. In alternative embodiments, the module terminals 480 may be separately formed and inserted into the module housing 452.

Each module terminal 480 extends between a first end 482 and a second end 484. The module terminal 480 includes a main body 486 between the first and second ends 482, 484. In an exemplary embodiment, the module terminal 480 includes a mating pad 490 along the main body 486 or at the first end 482 configured to be mated with the corresponding sensing conductor 360 of the sensing cable 350. For example, the sensing conductor 360 may be welded to the mating pad 490 to electrically connect the sensing conductor 360 to the module terminal 480. The sensing conductor 360 may be coupled to the mating pad 490 by other processes in alternative embodiments. In the illustrated embodiment, the mating pad 490 is located at or proximate to the top 456 of the module housing 452. Other locations are possible in alternative embodiments. The mating pad 490 may extend across the top of the opening 468. The mating pad 490 may be accessible from above and/or from below, such as for welding to the sensing conductor 360.

In an exemplary embodiment, the module terminal 480 includes a terminating pad 492 along the main body 486 or at the second end 484. The terminating pad 492 is configured to be terminated to the control circuit board 410. For example, the terminating pad 492 may be welded or soldered to a circuit or conductor of the control circuit board 410. For example, the terminating pad 492 may be a solder pad or solder tail for soldering to the control circuit board 410. In the illustrated embodiment, the terminating pad 492 extends from the module housing 452. For example, the terminating pad 492 may extend from the first side 460 or the second side 462, such as proximate to the bottom 458. The terminating pad 492 may be at other locations in alternative embodiments. In various embodiments, the module terminals 480 may be arranged within the module housing 452 such that adjacent module terminals 480 are inverted 180° with the terminating pads 492 thereof extending in opposite directions from the first side 460 and the second side 462, respectively. By having every other terminating pad 492 extending an opposite direction, the module terminals 480 have good separation of voltage (for example, creepage performance), relative to each other and at the termination to the control circuit board 410.

FIG. 9 is a bottom perspective view of a portion of the control assembly 400 showing the control module 450 poised for mating with the control circuit board 410. The control circuit board 410 includes a substrate 412, which may be a layered circuit board. The control circuit board 410 includes an upper surface 414 and a lower surface 416. The control circuit board 410 includes a slot 418 between the upper and lower surfaces 414, 416. The slot 418 is sized and shaped to receive the control module 450. For example, the slot 418 may have a rectangular shape. The control module 450 is received in the slot 418 to form an inboard component, which reduces overall height of the control assembly 400. In alternative embodiments, the control circuit board 410 may be provided without the slot 418 and the control module 450 may be surface mounted to the upper surface 414 or the lower surface 416.

The control circuit board 410 includes control circuits 420 (also referred to as control circuit terminations) configured to be mated with the corresponding module terminals 480 of the control module 450. The control circuits 420 may be pads, traces, vias, or other circuits of the control circuit board 410. In the illustrated embodiment, the control circuits 420 are provided at the lower surface 416. Other locations are possible in alternative embodiments, such as at the upper surface 414. In the illustrated embodiment, the control circuits 420 are arranged on opposite sides of the slot 418 for mating with the terminating pads 492 of the module terminals 480, which extend from opposite sides of the control module 450. By having every other control circuit 420 on opposite sides of the slot 418, the control circuits 420 have good separation of voltage (for example, creepage performance), relative to each other. Other arrangements of the control circuits 420 are possible in alternative embodiments, such as having all of the control circuits 420 arranged on the same side of the slot 418.

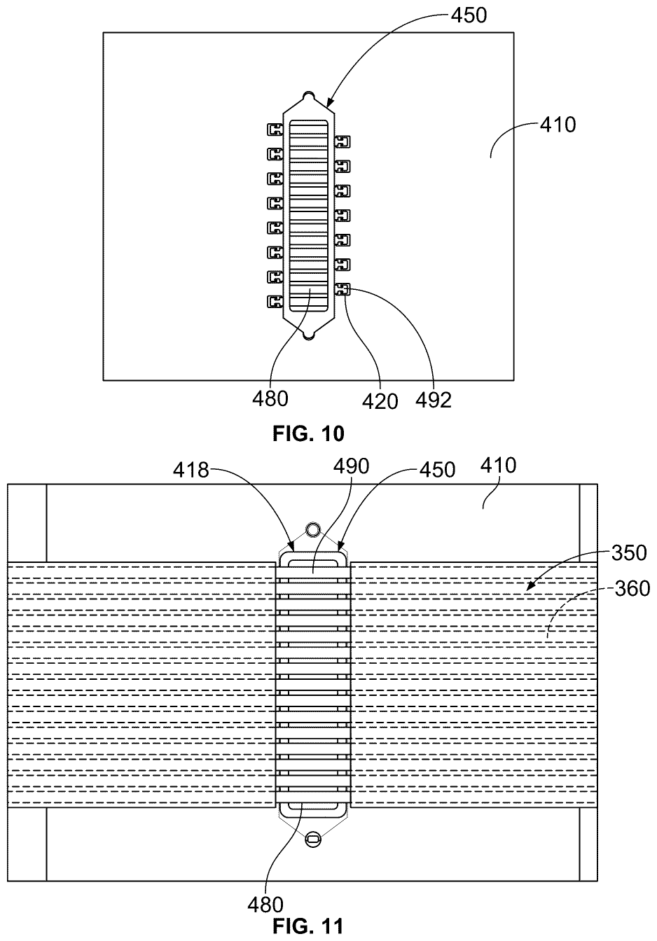

FIG. 10 is a bottom view of the control assembly 400 in accordance with an exemplary embodiment. FIG. 11 is a top view of the control assembly 400 in accordance with an exemplary embodiment. FIGS. 10 and 11 illustrate the control module 450 coupled to the control circuit board 410. FIG. 11 also illustrates the sensing cable 350 coupled to the control module 450. In an exemplary embodiment, the control module 450 is received in the slot 418 of the control circuit board 410. The module terminals 480 are coupled to the control circuits 420, such as being soldered to the control circuits 420. The sensing conductors 360 of the sensing cable 350 are coupled to the module terminals 480. For example, the sensing conductors 360 may be welded to the mating pads 490 of the corresponding module terminals 480.

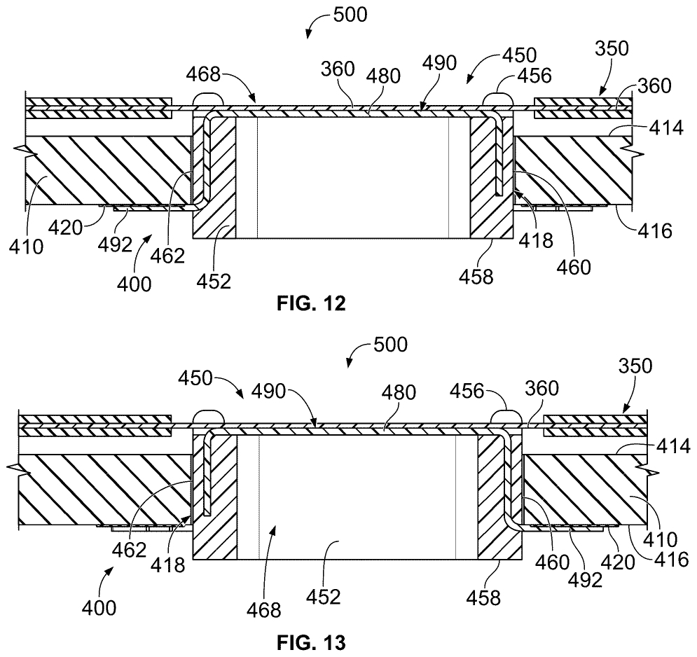

FIG. 12 is a cross-sectional view of the control assembly 400 in accordance with an exemplary embodiment. FIG. 13 is a cross-sectional view of the control assembly 400 in accordance with an exemplary embodiment. FIGS. 12 and 13 are sectioned through different module terminals 480 having the terminating pads 492 extending in opposite directions at opposite sides of the module housing 452. FIGS. 12 and 13 illustrate the control module 450 coupled to the control circuit board 410. FIGS. 12 and 13 illustrate the sensing cable 350 coupled to the control module 450.

When assembled, the control module 450 is received in the slot 418 of the control circuit board 410. In an exemplary embodiment, the top 456 of the module housing 452 is located above the upper surface 414 of the control circuit board 410 and the bottom 458 of the module housing 452 is located below the lower surface 416 of the control circuit board 410. In an exemplary embodiment, the terminating pads 492 of the module terminals 480 extend from the module housing 452 proximate to the bottom 458. The terminating pads 492 of different, adjacent module terminals 480 extend from the different sides 460, 462 of the module housing 452. The terminating pads 492 are coupled to the control circuits 420, such as being soldered to the control circuits 420, at the lower surface 416 of the control circuit board 410.

The mating pads 490 of the module terminals 480 are located at the top 456. The mating pads 490 are located above the control circuit board 410. The sensing conductors 360 of the sensing cable 350 are terminated to the mating pads 490. For example, the sensing conductors 360 may be welded to the outer surfaces of the mating pads 490. In an exemplary embodiment, the opening 468 provides access to the mating pads 490, such as from above and/or below the mating pads 490, for welding the sensing conductors 360 to the mating pad 490. In an exemplary embodiment, the sensing cable 350 extends along the upper surface 414 of the control circuit board 410. In various embodiments, the sensing cable 350 may be at a height above the upper surface 414, such as slightly elevated above the control circuit board 410. However, the sensing cable 350 may be in close proximity to the control circuit board 410 such that the control assembly 400 has an overall low profile height.

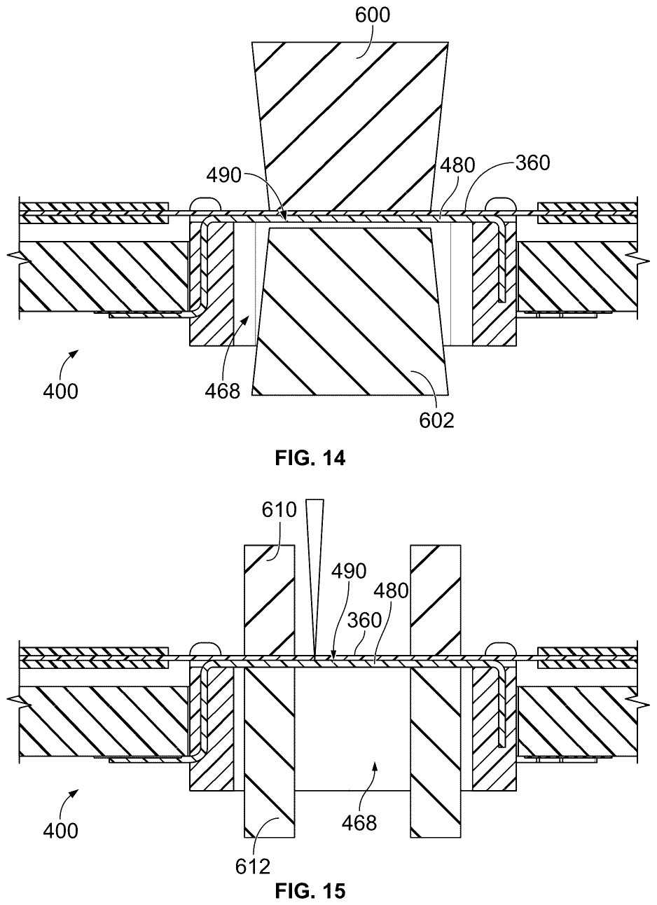

FIG. 14 is a cross-sectional view of the control assembly 400 in accordance with an exemplary embodiment showing the sensing conductor 360 being terminated to the module terminal 480 by an ultrasonic welding process. The opening 468 provides two sided access to the mating pad 490 of the module terminal 480 in the joining area for an ultrasonic horn 600 and anvil 602 to perform the ultrasonic welding process.

FIG. 15 is a cross-sectional view of the control assembly 400 in accordance with an exemplary embodiment showing the sensing conductor 360 being terminated to the module terminal 480 by a laser welding process. The opening 468 provides two sided access to the mating pad 490 of the module terminal 480 in the joining area for a top clamp jig 610 and a bottom clamp jig 612 to perform the laser welding process.

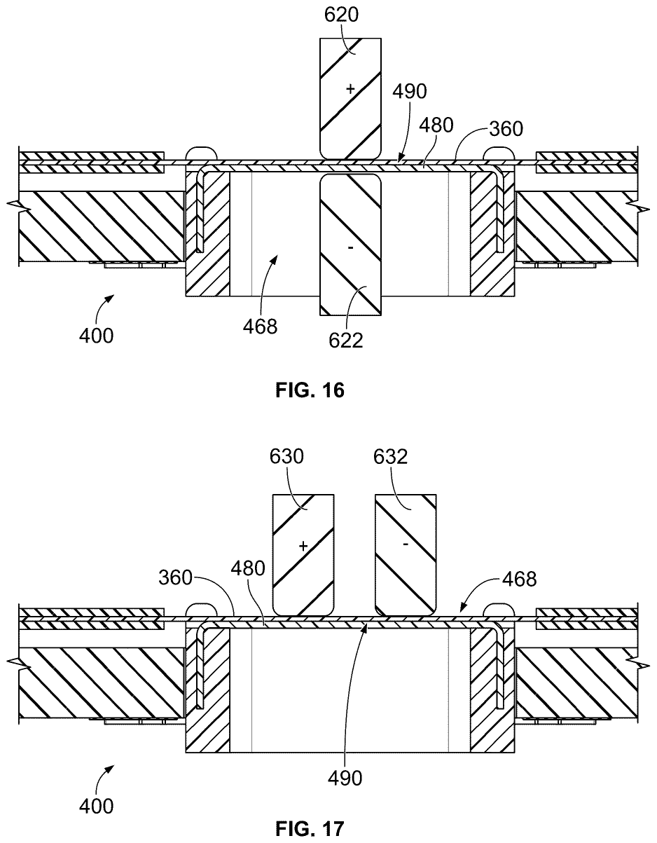

FIG. 16 is a cross-sectional view of the control assembly 400 in accordance with an exemplary embodiment showing the sensing conductor 360 being terminated to the module terminal 480 by a resistance welding process. The opening 468 provides two sided access to the mating pad 490 of the module terminal 480 in the joining area for an upper resistance welding tip 620 and a lower resistance welding tip 622 to perform the resistance welding process.

FIG. 17 is a cross-sectional view of the control assembly 400 in accordance with an exemplary embodiment showing the sensing conductor 360 being terminated to the module terminal 480 by a resistance welding process. The opening 468 provides access to the mating pad 490 of the module terminal 480 in the joining area for resistance welding tips 630, 632, which may be from above or below, depending on the type of resistance welding.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. § 112(f), unless and until such claim limitations expressly use the phrase “means for” followed by a statement of function void of further structure.

What is claimed is:

1. A battery pack interconnect assembly for electrically connecting cell terminals of battery cells in a battery pack, the battery pack interconnect assembly comprising:
a busbar interconnect including a plurality of busbars arranged in a matrix having multiple rows of the busbars and multiple columns of the busbars and a busbar carrier holding the busbars, each busbar including a first mating end for mating with the corresponding cell terminal of the corresponding battery cell and a second mating end for mating with the adjacent cell terminal of the adjacent corresponding battery cell, the busbars electrically connecting the battery cells in the battery pack; and
a sensing assembly coupled to the busbars for sensing at least one parameter of the busbars, the sensing assembly including a control assembly and a sensing harness coupled to the control assembly, the sensing harness having sensing cables with sensing conductors coupled to the busbars at sensing points, the control assembly including a control circuit board and control modules coupled to control circuits of the control circuit board, each control module including module terminals coupled between the control circuits and the corresponding sensing conductors.

2. The battery pack interconnect assembly of claim 1, wherein the control circuit board aggregates signals from each of the control modules and corresponding sensing cables presenting the parameters from all of the sensing conductors.

3. The battery pack interconnect assembly of claim 1, wherein the control circuit board includes slots receiving the control modules.

4. The battery pack interconnect assembly of claim 1, wherein the control circuit board has an upper surface and a lower surface, the control circuit board including slots between the upper and lower surfaces, the slots receiving the control modules.

5. The battery pack interconnect assembly of claim 4, wherein the module terminals of the control modules are coupled to the control circuits of the control circuit board at the lower surface, the sensing cables extending along the upper surface of the control circuit board.

6. The battery pack interconnect assembly of claim 5, wherein the sensing conductors of the sensing cables are terminated to the module terminals at a height above the upper surface.

7. The battery pack interconnect assembly of claim 1, wherein each control module includes a module housing holding the module terminals, the module housing having a top and a bottom, the top located above an upper surface of the control circuit board, the bottom located below a lower surface of the control circuit board.

8. The battery pack interconnect assembly of claim 7, wherein the module housing includes a first side and a second side opposite the first side extending between the top and the bottom, the module terminals including mating pads and terminating pads, the mating pads located at the top and configured to be connected to the sensing conductors of the corresponding sensing cable, the terminating pads of a first subset of the module terminals located at the first side of the module housing, the terminating pads of a second subset of the module terminals located at the second side of the module housing.

9. The battery pack interconnect assembly of claim 1, wherein each control module includes a module housing holding the module terminals, the module housing having a top and a bottom, the module housing having a first wall, a second wall, and a cavity between the first and second walls, the first wall supporting first ends of the module terminals, the second wall supporting second ends of the module terminals, the module housing being open above and below the module terminals between the first and second walls to expose the upper and lower surfaces of the module terminals.

10. The battery pack interconnect assembly of claim 1, wherein the sensing conductors of the sensing cables extend parallel to each other and a conductor pitch and the module terminals of the control modules extend parallel to each other at a terminal pitch equal to the conductor pitch.

11. The battery pack interconnect assembly of claim 1, wherein the sensing cable includes a module window exposing all of the sensing conductors in the module window, the module window aligned with the corresponding control module, wherein exposed portions of the sensing conductors in the module window are terminated to the corresponding module terminals in the module window.

12. The battery pack interconnect assembly of claim 1, wherein the module terminals include mating pads, the sensing conductors being welded to the corresponding mating pads.

13. The battery pack interconnect assembly of claim 1, wherein the sensing harness includes sensing modules coupled to the sensing cables, the sensing modules including sensing circuits electrically connected to the corresponding busbars at the sensing points to sense the parameters of each of the corresponding busbars, the sensing cables spanning between the sensing modules in a row with the sensing conductors electrically connected to the corresponding sensing circuits of the corresponding sensing modules.

14. The battery pack interconnect assembly of claim 1, wherein the sensing cables are flat flexible cables having flat conductors defining the sensing conductors, the sensing conductors extending parallel to each other and being surrounded by an insulator, portions of the insulator being removed to form access windows to the sensing conductors at joining points.

15. The battery pack interconnect assembly of claim 14, wherein the access windows expose different sensing conductors at each of the corresponding busbars to electrically connect to different busbars.

16. A sensing assembly for sensing parameters of busbars electrically connected to cell terminals of battery cells in a battery pack, the sensing assembly comprising:
a sensing harness including sensing modules and sensing cables coupled to the sensing modules, the sensing modules configured to be electrically connected to the corresponding busbars at sensing points to sense the sensing parameters of each of the corresponding busbars, each sensing module including a sensing housing and a sensing circuit held by the sensing housing, the sensing circuits configured to be electrically connected to the corresponding busbars, the sensing cables extending parallel to each other in rows, the sensing cables being flat flexible cables having a plurality of sensing conductors, the sensing cables spanning each of the sensing modules, the sensing conductors being electrically connected to the corresponding sensing circuits of each of the sensing modules; and
a control assembly coupled to the sensing cables of the sensing harness, the control assembly including a control circuit board and control modules coupled to the control circuit board, each control module including module terminals coupled to control circuits of the control circuit board, the module terminals including mating portions coupled to the sensing conductors of the corresponding sensing cable, the control modules electrically connecting the corresponding sensing cable to the control circuit board.

17. The sensing harness of claim 16, wherein the control circuit board has an upper surface and a lower surface, the control circuit board including slots between the upper and lower surfaces, the slots receiving the control modules.

18. The sensing harness of claim 16, wherein the sensing cable includes a module window exposing all of the sensing conductors in the module window, the module window aligned with the corresponding control module, wherein exposed portions of the sensing conductors in the module window are terminated to the corresponding module terminals in the module window.

19. The sensing harness of claim 16, wherein the module terminals include mating pads, the sensing conductors being welded to the corresponding mating pads.

20. A battery pack comprising:
battery cells arranged in a matrix having multiple rows and multiple columns of the battery cells, each battery cell including a first cell terminal and a second cell terminal; and
a battery pack interconnect assembly electrically connected to the first and second cell terminals of the battery cells, the battery pack interconnect assembly including a busbar interconnect and a sensing assembly electrically connected to the busbar interconnect;
the busbar interconnect including a plurality of busbars arranged in a matrix having multiple rows of the busbars and multiple columns of the busbars and a busbar carrier holding the busbars, each busbar including a first mating end for mating with the first cell terminal of the corresponding battery cell and a second mating end for mating with the second cell terminal of the adjacent corresponding battery cell, the busbars electrically connecting the battery cells in the battery pack;
the sensing assembly including a sensing harness and a control assembly coupled to the sensing harness;
the sensing harness including sensing modules and sensing cables coupled to the sensing modules, the sensing modules electrically connected to the corresponding busbars at sensing points to sense sensing parameters of each of the corresponding busbars, each sensing module including a sensing housing and a sensing circuit held by the sensing housing, the sensing circuits configured to be electrically connected to the corresponding busbars, the sensing cables extending parallel to each other in rows, the sensing cables being flat flexible cables having a plurality of sensing conductors, the sensing cables spanning each of the sensing modules, the sensing conductors being electrically connected to the corresponding sensing circuits of each of the sensing modules; and
the control assembly coupled to the sensing cables of the sensing harness, the control assembly including a control circuit board and control modules coupled to the control circuit board, each control module including module terminals coupled to control circuits of the control circuit board, the module terminals including mating portions coupled to the sensing conductors of the corresponding sensing cable, the control modules electrically connecting the corresponding sensing cable to the control circuit board.
